(19) United States
(12) Patent Application Publication
(10) Pub. No.: US 2013/0009796 A1
(43) Pub. Date: Jan. 10, 2013

(54) CLOCK GENERATOR CIRCUIT FOR SUCCESSIVE APPROXIMATIOM ANALOG TO-DIGITAL CONVERTER

(75) Inventors: Shiro Sakiyama, Kyoto (JP); Akinori Matsumoto, Osaka (JP); Yusuke Tokunaga, Kyoto (JP); Ichiro Kuwabara, Ehime (JP)

(73) Assignee: Panasonic Corporation, Osaka (JP)

(21) Appl. No.: 13/620,473

(22) Filed: Sep. 14, 2012

Related U.S. Application Data
(63) Continuation of application No. PCT/JP2010/006065, filed on Oct. 13, 2010.

(30) Foreign Application Priority Data
Mar. 29, 2010 (JP) 2010-075372

(51) Int. Cl. H03M 1/38

(52) U.S. Cl. 341/110

(57) ABSTRACT

A sampling clock generator generates a sampling clock based on a reference clock and an internal clock. An internal clock generator causes, during a period in which the sampling clock is at a second voltage level, the internal clock to transition from a first voltage level to a second voltage level when a first comparison signal and a second comparison signal transition to voltage levels different from each other, and the internal clock to transition from the second voltage level to the first voltage level after a variable delay time has elapsed when the first and second comparison signals transition to a same voltage level. A delay controller controls the variable delay time in the internal clock generator so that the ratio of a period in which the sampling clock is at a first voltage level to a period of the reference clock approaches a predetermined ratio.

### CROSS-REFERENCE TO RELATED APPLICATION

This is a continuation of PCT International Application PCT/JP2010/006065 filed on Oct. 13, 2010, which claims priority to Japanese Patent Application No. 2010-075372 filed on Mar. 29, 2010. The disclosures of these applications including the specifications, the drawings, and the claims are hereby incorporated by reference in its entirety.

### BACKGROUND

The technology disclosed in this specification relates to clock generator circuits, and more particularly to circuits for generating sampling clocks and internal clocks used in successive approximation analog-to-digital converters (ADCs).

Today, successive approximation ADCs are known as ADCs which are implemented using relatively simple circuit configurations, are highly compatible with relatively low-cost CMOS fabrication processes, and can achieve both a moderate conversion rate and a moderate conversion accuracy, thereby having wide application in manufacturing (see, e.g., Michiel van Elzakker, et al., “A 1.9 μW 4.4fJ/Conversion-step 10b 1 MS/s Charge-Redistribution ADC” in IEEE ISSCC Dig. Tech. Papers, February 2008, pp. 244-245 (Non-Patent Document 1), etc.).

FIG. 15 shows an example configuration of a successive approximation ADC. This successive approximation ADC converts an analog signal Vin into a four-bit digital signal, and includes a capacitive digital-to-analog converter (DAC) 91 and a differential latched comparator 92. The capacitive DAC 91 includes capacitors 901-904, a sampling switch SW9, and a controller 911. The differential latched comparator 92 includes a precharged comparator 921 and a latch circuit 922. Assuming the capacitance value of the capacitor 904 to be C₀, the capacitance values of the capacitors 903, 902, and 901 are respectively 2C₀, 4C₀ and 8C₀. This successive approximation ADC is supplied with a sampling clock SCK and an internal clock ICK as shown in FIG. 16.

[High-Level Period Ts9 of Sampling Clock]

During a high-level period (period in which a signal is at a high logic level) of the sampling clock SCK, the controller 911 initializes a control voltage V1 to a high logic level (e.g., supply voltage), and initializes each of control voltages V2-V4 to a low logic level (e.g., ground voltage). The sampling switch SW9 is switched from an Off state to an On state in synchronism with a rising edge of the sampling clock SCK, and is switched from an On state to an Off state in synchronism with a falling edge of the sampling clock SCK. This operation causes an analog voltage Vs dependent on the signal level of the analog signal Vin to be sampled at a sampling node Ns9.

[High-Level Period T91 of Internal Clock]

If the analog voltage Vs is lower than a reference voltage VREF, the precharged comparator 921 causes a transition of a comparison signal QP from a high logic level (e.g., supply voltage) to a low logic level (e.g., ground voltage), and maintains a comparison signal QN at the high logic level, in synchronism with a rising edge of the internal clock ICK. In contrast, if the analog voltage Vs is not lower than the reference voltage VREF, the precharged comparator 921 maintains the comparison signal QP at the high logic level, and causes a transition of the comparison signal QN from the high logic level to the low logic level, in synchronism with a rising edge of the internal clock ICK. If the comparison signals QP and QN are respectively at the low logic level and at the high logic level, the latch circuit 922 sets a bit value DB to “0” (e.g., ground voltage). Conversely, if the comparison signals QP and QN are respectively at the high logic level and at the low logic level, the latch circuit 922 sets the bit value DB to “1” (e.g., supply voltage).

[Low-Level Period T92 of Internal Clock]

The precharged comparator 921 causes a transition of both of the comparison signals QP and QN to the high logic level in synchronism with a falling edge of the internal clock ICK. If both of the comparison signals QP and QN are at the high logic level, the latch circuit 922 holds the bit value DB without changing. If the bit value DB is “0” in the i-th (where i=1-3) low-level period (period in which a signal is at a low logic level) T92 of the internal clock ICK, then the controller 911 switches the (i+1)th control voltage (represented hereinafter as the control voltage V(i+1)) of the control voltages V1-V4 from the low logic level to the high logic level in synchronism with the i-th falling edge of the internal clock ICK. Conversely, if the bit value DB is “1” in the i-th low-level period T92 of the internal clock ICK, then the controller 911 switches the i-th control voltage (represented hereinafter as the control voltage Vi) of the control voltages V1-V4 from the high logic level to the low logic level, and switches the control voltage V(i+1) from the low logic level to the high logic level, in synchronism with the i-th falling edge of the internal clock ICK. This operation redistributes the electrical charges stored in the capacitors 901-904, thereby causing the analog voltage Vs to approach the reference voltage VREF.

As described above, during a high-level period T91 of the internal clock ICK, the differential latched comparator 92 performs a comparison process; in contrast, during a low-level period T92 of the internal clock ICK, the capacitive DAC 91 performs a charge redistribution process. Thus, it is important to ensure the comparison time (the time needed for the comparison process: e.g., comparator delay time, etc.) in a high-level period of the internal clock ICK, and to ensure the charge redistribution time (the time needed for the charge redistribution process: e.g., a delay time introduced by the control logic in the controller 911, a settling time in charge redistribution, etc.) in a low-level period T92 of the internal clock ICK.

Conventionally, the sampling clock SCK and the internal clock ICK are respectively generated based on high-speed clocks having higher frequencies than those of the sampling clock SCK and of the internal clock ICK. In addition, since the comparison time and the charge redistribution time may vary due to process variations, supply voltage variations, and temperature variations (PVT variations), the respective pairs of the high-level and low-level periods of the sampling clock SCK and of the internal clock ICK are set in consideration of the worst cases of the comparison time and of the charge redistribution time. These factors create difficulties in increasing the rates of the sampling clock SCK and of the internal clock ICK.

Shuo-Wei Michael Chen, et al., “A 6-bit 600-MS/s 5.3-mW Asynchronous ADC in 0.13-μm CMOS” IEEE J. Solid-State Circuits, Vol. 41, No. 12, pp. 2669-2680, December 2006 (Non-Patent Document 2) describes a configuration in which an oscillator circuit having a comparator, of a successive approximation ADC generates an internal clock, thereby allowing the high-level period of the internal clock to be changed based on the variation of the comparator delay time. According to Non-Patent Document 2, the time needed for the comparison process can be ensured in the high-level period of the internal clock, and therefore the rate of the internal clock can be increased as compared to when the high-level period of the internal clock is set in consideration of the worst case of the comparator delay time.

### SUMMARY

However, according to the technology described in Non-Patent Document 2, even if the high-level period of the internal clock can be ensured so that the comparison process completes within the high-level period of the internal clock, the low-level period of the internal clock may fail to be appropriately ensured. For example, a variation in the period of self-oscillation of the oscillator circuit due to PVT variations causes not only the high-level period of the internal clock to vary, but also the low-level period of the internal clock to vary. If the low-level period of the internal clock is excessively long, then the end of a pulse (high-level period) of the internal clock may exceed the low-level period of the sampling clock, which may cause the successive approximation ADC to malfunction. On the other hand, if the low-level period of the internal clock is shorter than the charge redistribution time, then the charge redistribution process may not complete within the low-level period of the internal clock.

According to one aspect of the present invention, a clock generator circuit is a circuit for generating a sampling clock and an internal clock used in a successive approximation analog-to-digital converter (ADC) which converts a first analog signal and a second analog signal, whose voltage levels vary in a complementary fashion with respect to each other, into an n-bit (where n≧2) digital signal, where the successive approximation ADC includes a first capacitive digital-to-analog converter (DAC), a second capacitive DAC, and a differential latched comparator, and the clock generator circuit includes a sampling clock generator configured to generate the sampling clock, an internal clock generator configured to generate the internal clock, and a delay controller; during a period in which the sampling clock is at a first voltage level, the first and second capacitive DACs respectively store electrical charges dependent on signal levels of the first and second analog signals, and respectively sample a first analog voltage and a second analog voltage dependent on the signal levels of the first and second analog signals; during a period in which the internal clock is at a first voltage level, the differential latched comparator changes voltages of a first comparison signal and a second comparison signal to voltage levels different from each other based on which of the first or second analog voltage is higher, and outputs as the digital signal a bit value dependent on the first and second comparison signals; during a period in which the internal clock is at a second voltage level, the differential latched comparator changes the voltages of the first and second comparison signals to a same voltage level, and holds the bit value, and the first and second capacitive DACs respectively control the electrical charges stored in the first and second capacitive DACs based on the bit value so that the first and second analog voltages approach each other; the sampling clock generator causes the sampling clock to transition from the first voltage level to a second voltage level when a reference clock, which defines a sampling period of the successive approximation ADC, transitions from a second voltage level to a first voltage level, and causes the sampling clock to transition from the second voltage level to the first voltage level after transitions of the internal clock from the first voltage level to the second voltage level have occurred n times during a period in which the sampling clock is at the second voltage level; the internal clock generator maintains the internal clock at the second voltage level during the period in which the sampling clock is at the first voltage level, causes the internal clock to transition from the second voltage level to the first voltage level when the sampling clock transitions from the first voltage level to the second voltage level, and causes, during the period in which the sampling clock is at the second voltage level, the internal clock to transition from the first voltage level to the second voltage level when the first and second comparison signals transition from the same voltage level to the voltage levels different from each other, and the internal clock to transition from the second voltage level to the first voltage level after a variable delay time has elapsed when the first and second comparison signals transition from the voltage levels different from each other to the same voltage level; and the delay controller controls the variable delay time in the internal clock generator so that a ratio of the period in which the sampling clock is at the first voltage level to a period of the reference clock approaches a predetermined ratio.

According to the clock generator circuit described above, each of the n first-voltage level periods of the internal clock (periods in which the internal clock is at the first voltage level) includes the delay time of the differential latched comparator, thereby allowing the comparison time (the time needed for the differential latched comparator to perform the comparison process) to be ensured in each of the n first-voltage level periods of the internal clock.

In addition, since the variable delay time in the internal clock generator is controlled so that the ratio of the first-voltage level period of the sampling clock (period in which the sampling clock is at the first voltage level) to the period of the reference clock approaches a predetermined ratio, the first-voltage level period of the sampling clock can be ensured, and the n first-voltage level periods of the internal clock can be accommodated within the second-voltage level period of the sampling clock (period in which the sampling clock is at the second voltage level).

Moreover, the remaining period which is obtained by subtracting the n first-voltage level periods of the internal clock from the second-voltage level period of the sampling clock can be distributed nearly evenly as (n−1) second-voltage level periods of the internal clock (periods in which the internal clock is at the second voltage), thereby facilitating ensuring the charge redistribution time (the time needed for the capacitive DACs to perform the charge redistribution process) in each of the (n−1) second-voltage level periods of the internal clock.

The internal clock generator may include a first logic circuit configured to set a first internal signal to the first voltage level if the first and second comparison signals are at the voltage levels different from each other, and to set the first internal signal to the second voltage level if the first and second comparison signals are at the same voltage level; a variable delay unit configured to delay the transition of the first internal signal from the first voltage level to the second voltage level by the variable delay time, and to output a resultant signal as a second internal signal; and a second logic circuit configured to set the internal clock to the first voltage level if both of the sampling clock and the second internal signal are at the second voltage level, and to set the internal clock to the second voltage level if at least one of the sampling clock or the second internal signal is at the first voltage level.

The delay controller may include a voltage generator configured to generate a control voltage so that a ratio of a voltage level of the control voltage to the first voltage level of the sampling clock is the predetermined ratio; and a ratio controller configured to control the variable delay time in the internal clock generator so that a direct current (DC) level of the sampling clock approaches the voltage level of the control voltage.

The sampling clock generator may include a counter configured, during the period in which the sampling clock is at the second voltage level, to count a number of transitions of the internal clock from the first voltage level to the second voltage level, and to cause the sampling clock to transition from the second voltage level to the first voltage level when the number of transitions reaches the value n, and a counter controller configured to cause the sampling clock to transition from the first voltage level to the second voltage level when the reference clock transitions from the second voltage level to the first voltage level.

The predetermined ratio may be able to be variably controlled. Such a configuration allows the period in which the sampling clock is at the first voltage level to be adjusted. For example, the first-voltage level period of the sampling clock can be set based on the specifications (e.g., a settling time in a sampling process) of the successive approximation ADC.

The value of n may be able to be variably controlled. Such a configuration allows the number of pulses (the number of the first-voltage level periods) of the internal clock to be adjusted. For example, the number of pulses of the internal clock can be set based on the specifications (e.g., the number of bits) of the successive approximation ADC.

According to another aspect of the present invention, a clock generator circuit is a circuit for generating a sampling clock and an internal clock used in a successive approximation analog-to-digital converter (ADC) which converts an analog signal into an n-bit (where n≧2) digital signal, where the successive approximation ADC includes a capacitive digital-to-analog converter (DAC) and a differential latched comparator, and the clock generator circuit includes a sampling clock generator configured to generate the sampling clock, an internal clock generator configured to generate the internal clock, and a delay controller; during a period in which the sampling clock is at a first voltage level, the capacitive DAC stores an electrical charge dependent on a signal level of the analog signal, and samples an analog voltage dependent on the signal level of the analog signal; during a period in which the internal clock is at a first voltage level, the differential latched comparator changes voltages of a first comparison signal and a second comparison signal to voltage levels different from each other based on which of a reference voltage or the analog voltage is higher, and outputs as the digital signal a bit value dependent on the first and second comparison signals; during a period in which the internal clock is at a second voltage level, the differential latched comparator changes the voltages of the first and second comparison signals to a same voltage level, and holds the bit value, and the capacitive DAC controls the electrical charge stored in the capacitive DAC based on the bit value so that the analog voltage approaches the reference voltage; the sampling clock generator causes the sampling clock to transition from the first voltage level to a second voltage level when a reference clock, which defines a sampling period of the successive approximation ADC, transitions from a second voltage level to a first voltage level, and causes the sampling clock to transition from the second voltage level to the first voltage level after transitions of the internal clock from the first voltage level to the second voltage level have occurred n times during a period in which the sampling clock is at the second voltage level; the internal clock generator maintains the internal clock at the second voltage level during the period in which the sampling clock is at the first voltage level, causes the internal clock to transition from the second voltage level to the first voltage level when the sampling clock transitions from the first voltage level to the second voltage level, and causes, during the period in which the sampling clock is at the second voltage level, the internal clock to transition from the first voltage level to the second voltage level when the first and second comparison signals transition from the same voltage level to the voltage levels different from each other, and the internal clock to transition from the second voltage level to the first voltage level after a variable delay time has elapsed when the first and second comparison signals transition from the voltage levels different from each other to the same voltage level; and the delay controller controls the variable delay time in the internal clock generator so that a ratio of the period in which the sampling clock is at the first voltage level to a period of the reference clock approaches a predetermined ratio.

According to the clock generator circuit described above, the comparison time can be ensured in each of the n first-voltage level periods of the internal clock. Moreover, the first-voltage level period of the sampling clock can be ensured, and the n first-voltage level periods of the internal clock can be accommodated within the second-voltage level period of the sampling clock. Furthermore, the remaining period which is obtained by subtracting the n first-voltage level periods of the internal clock from the second-voltage level period of the sampling clock can be distributed nearly evenly as (n−1) second-voltage level periods of the internal clock, thereby facilitating ensuring the charge redistribution time in each of the (n−1) second-voltage level periods of the internal clock.

### BRIEF DESCRIPTION OF THE DRAWINGS

FIG. 1 is diagram illustrating an example configuration of a clock generator circuit for a successive approximation ADC.

FIG. 2 is a diagram suitable for explaining an operation of the successive approximation ADC.

FIG. 3 is a diagram illustrating an example configuration of the differential latched comparator.

FIG. 4 is a diagram illustrating an example configuration of the sampling clock generator.

FIG. 5 is a diagram suitable for explaining an operation of the sampling clock generator.

FIG. 6 is a diagram illustrating an example configuration of the variable delay unit.

FIG. 7 is a diagram suitable for explaining an operation of the internal clock generator.

FIG. 8 is a diagram illustrating an example configuration of the delay controller.

FIG. 9 is a diagram suitable for explaining an operation of the delay controller.

FIG. 10 is a diagram suitable for explaining another operation of the delay controller.

FIG. 11 is a diagram suitable for explaining a variation of the sampling clock generator.

FIG. 12 is a diagram suitable for explaining an operation of the sampling clock generator of FIG. 11.

FIG. 13 is a diagram suitable for explaining a differential successive approximation ADC.

FIG. 14 is a diagram suitable for explaining an operation of the differential successive approximation ADC.

FIG. 15 is a diagram illustrating an example configuration of a successive approximation ADC.

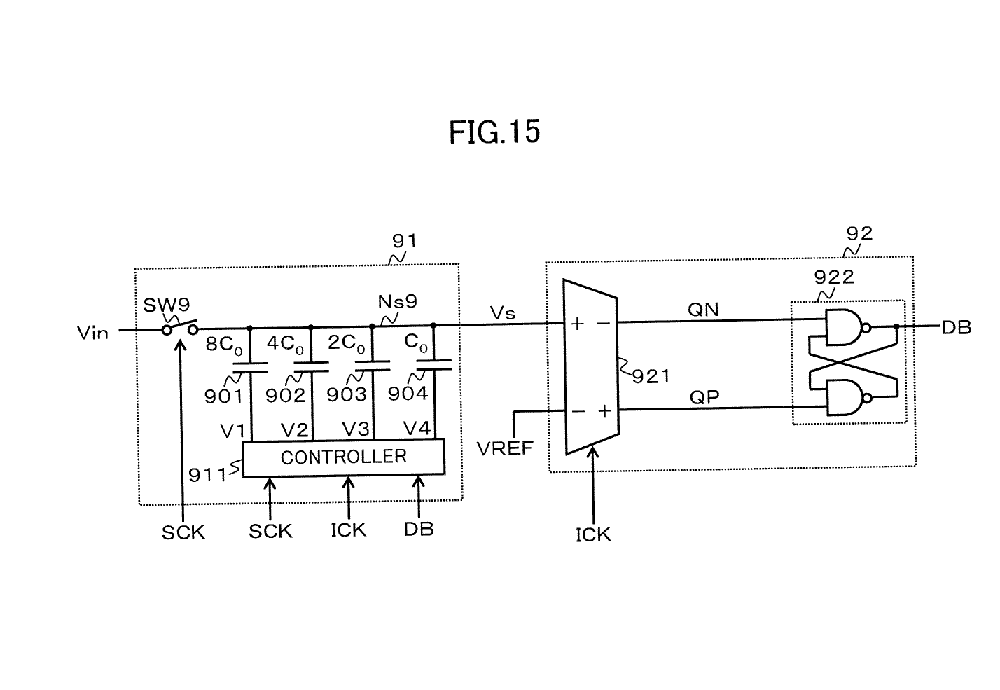

FIG. 16 is a diagram suitable for explaining a sampling clock and an internal clock.

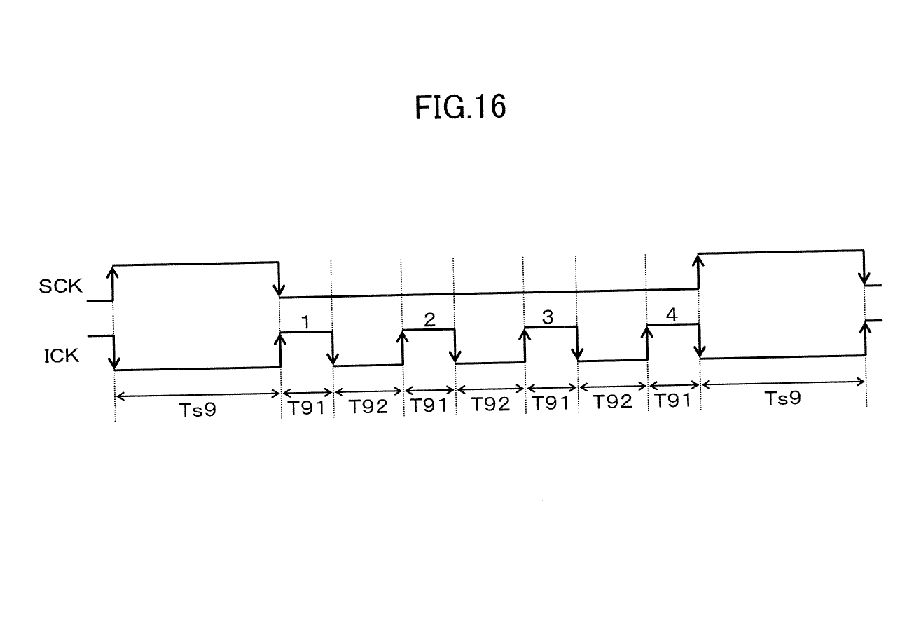

### DETAILED DESCRIPTION

Example embodiments will be described below in detail with reference to the drawings, in which like reference characters indicate the same or equivalent components, and the explanation thereof will not be repeated.

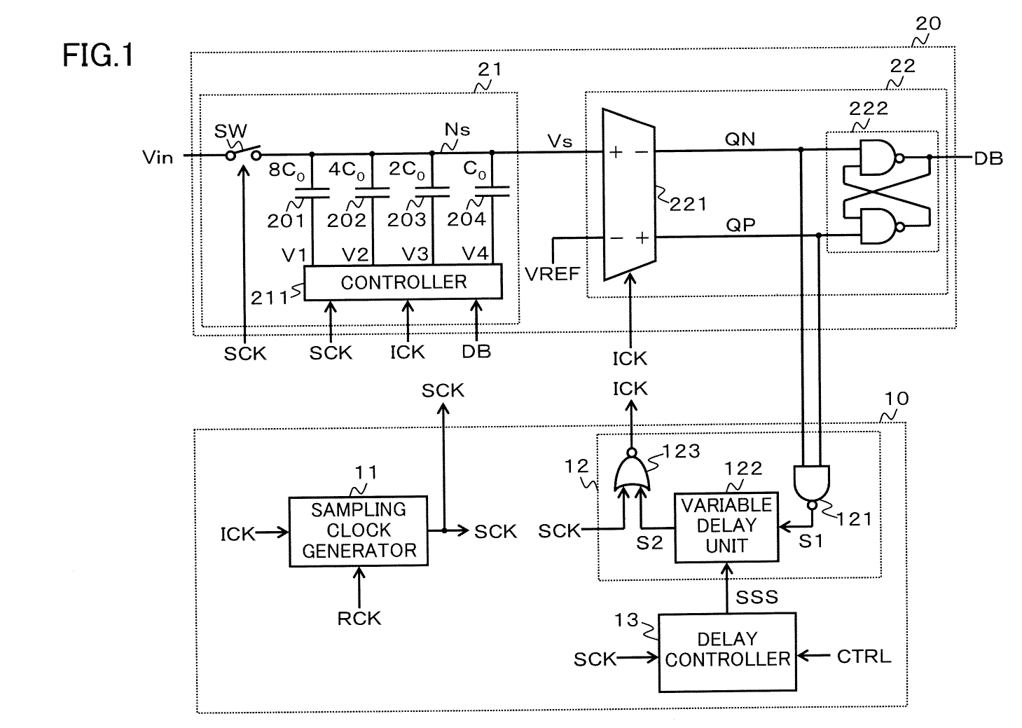

FIG. 1 illustrates an example configuration of a clock generator circuit 10 for a successive approximation ADC. The clock generator circuit 10 generates a sampling clock SCK and an internal clock ICK used in a successive approximation ADC 20.

(Successive Approximation ADC)

Before describing the clock generator circuit 10, the successive approximation ADC 20 will be described. The successive approximation ADC 20 converts an analog signal Vin into an n-bit (here n=4) digital signal, and includes a capacitive DAC 21 and a differential latched comparator 22. During a high-level period (period in which a signal is at a high logic level) of the sampling clock SCK, the capacitive DAC 21 stores an electrical charge dependent on the signal level of the analog signal Vin, and samples an analog voltage Vs dependent on the signal level of the analog signal Vin. During a high-level period of the internal clock ICK, the differential latched comparator 22 causes transitions of comparison signals QP and QN to voltage levels different from each other, based on which of the analog voltage Vs or a reference voltage VREF is higher, and outputs a bit value DB dependent on the comparison signals QP and QN, as the digital signal. During a low-level period (period in which a signal is at a low logic level) of the internal clock ICK, the differential latched comparator 22 causes transitions of the comparison signals QP and QN to a same voltage level, and holds the bit value DB. The capacitive DAC 21 controls the electrical charge stored in the capacitive DAC 21 based on the bit value DB so that the analog voltage Vs approaches the reference voltage VREF.

For example, the capacitive DAC 21 includes a sampling switch SW, a plurality of (here, four) capacitors 201-204, and a controller 211. The differential latched comparator 22 includes a precharged comparator 221 and a latch circuit 222. Here, the capacitance values of the capacitors 201-204 are binary weighted. For example, assuming the capacitance value of the capacitor 204 to be C₀, the capacitance values of the capacitors 203, 202, and 201 are respectively 2C₀, 4C₀, and 8C₀. One end of each of the capacitors 201-204 is coupled to a sampling node Ns, and the other ends of the capacitors 201-204 are respectively supplied with control voltages V1-V4.

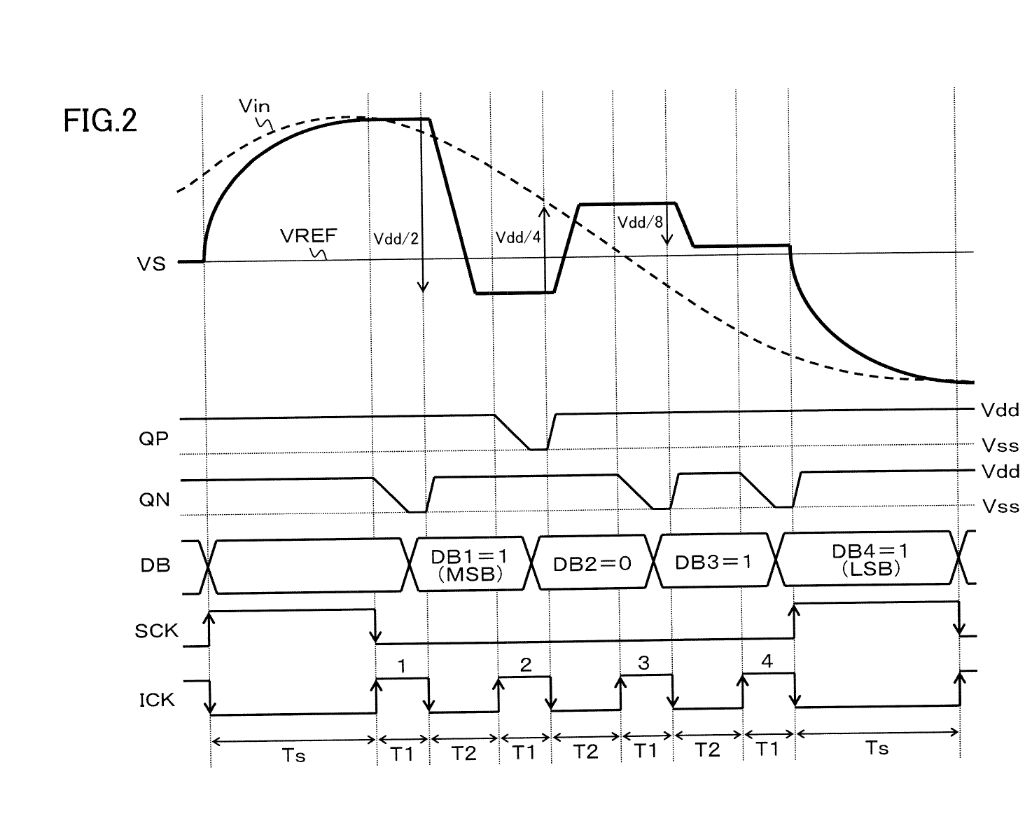

Next, referring to FIG. 2, the operation of the successive approximation ADC 20 will be described.

<<High-Level Period Ts of Sampling Clock>>

During a high-level period of the sampling clock SCK, the controller 211 initializes a control voltage V1 to a high logic level (e.g., supply voltage Vdd), and initializes each of control voltages V2-V4 to a low logic level (e.g., ground voltage Vss). The sampling switch SW is switched from an Off state to an On state in synchronism with a rising edge of the sampling clock SCK, and is switched from an On state to an Off state in synchronism with a falling edge of the sampling clock SCK. With this operation, electrical charges dependent on the signal level of the analog signal Vin are stored in the capacitors 201-204, and as shown in FIG. 2, the analog voltage Vs dependent on the signal level of the analog signal Vin is sampled at the sampling node Ns during a high-level period Ts of the sampling clock SCK.

<<High-Level Period T1 of Internal Clock>>

If the analog voltage Vs is lower than the reference voltage VREF, the precharged comparator 221 causes a transition of the comparison signal QP from a high logic level (e.g., supply voltage Vdd) to a low logic level (e.g., ground voltage Vss), and maintains the comparison signal QN at the high logic level, in synchronism with a rising edge of the internal clock ICK (in FIG. 2, the second rising edge of the internal clock ICK). In contrast, if the analog voltage Vs is not lower than the reference voltage VREF, the precharged comparator 221 maintains the comparison signal QP at the high logic level, and causes a transition of the comparison signal QN from the high logic level to the low logic level, in synchronism with a rising edge of the internal clock ICK (in FIG. 2, the first, third, and fourth rising edges of the internal clock ICK). If the comparison signals QP and QN are respectively at the low logic level and at the high logic level, the latch circuit 222 sets the bit value DB to “0” (e.g., ground voltage Vss). Conversely, if the comparison signals QP and QN are respectively at the high logic level and at the low logic level, the latch circuit 222 sets the bit value DB to “1” (e.g., supply voltage Vdd). For example, in FIG. 2, the transitions of the comparison signals QP and QN respectively to the high logic level and to the low logic level in the first high-level period T1 of the internal clock ICK causes the bit value DB to be set to “1.” That is, this operation determines that the first-bit value DB1 (MSB: most significant bit) is “1.” In this way, the bit values DB1-DB4 are respectively determined in the first to fourth high-level periods T1 of the internal clock ICK.

<<Low-Level Period T2 of Internal Clock>>

The precharged comparator 221 causes transitions of both of the comparison signals QP and QN to the high logic level in synchronism with a falling edge of the internal clock ICK. If both of the comparison signals QP and QN are at the high logic level, then the latch circuit 222 holds the bit value DB without changing. If the bit value DB is “0” in the i-th (here i=1-3) low-level period T2 of the internal clock ICK, then the controller 211 switches the (i+1)th control voltage (represented hereinafter as the control voltage V(i+1)) of the control voltages V1-V4 from the low logic level to the high logic level in synchronism with the i-th falling edge of the internal clock ICK. Conversely, if the bit value DB is “1” in the i-th low-level period T2 of the internal clock ICK, then the controller 211 switches the i-th control voltage (represented hereinafter as the control voltage Vi) of the control voltages V1-V4 from the high logic level to the low logic level, and switches the control voltage V(i+1) from the low logic level to the high logic level, in synchronism with the i-th falling edge of the internal clock ICK. For example, since the bit value DB1 is “1” during the first low-level period T2 of the internal clock ICK, the controller 211 switches the control voltage VI from the high logic level to the low logic level, and switches the control voltage V2 from the low logic level to the high logic level, in synchronism with the first falling edge of the internal clock ICK.

[Precharged Comparator]

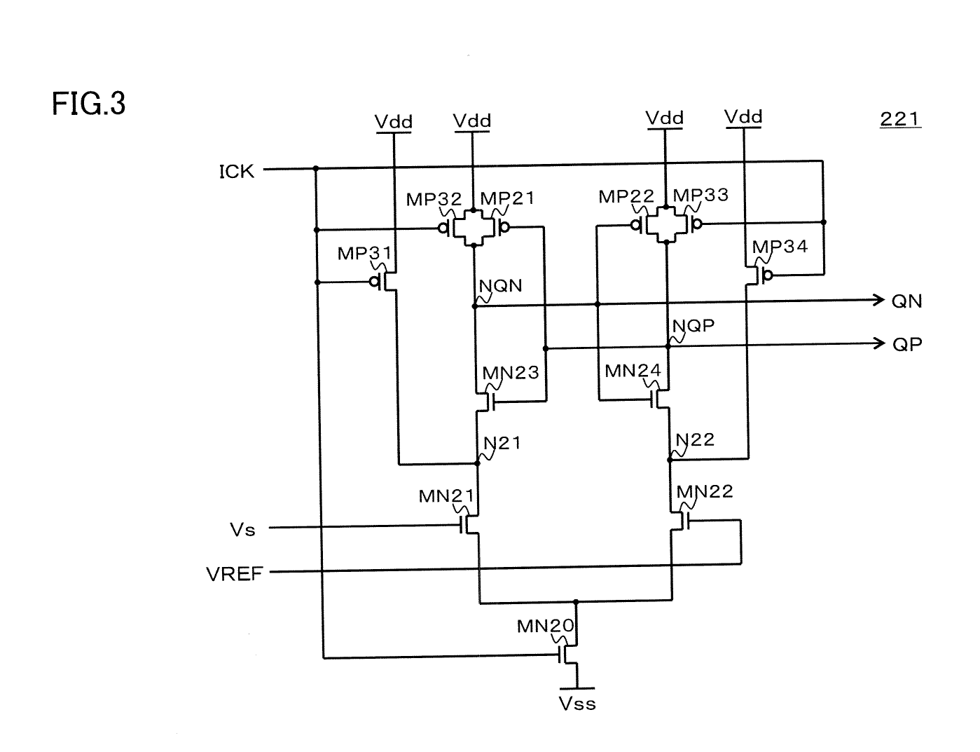

As shown in FIG. 3, the precharged comparator 221 may include a current source transistor MN20, a pair of differential transistors MN21 and MN22, latch transistors MN23, NM24, MP21, and MP22, and precharge transistors MP31-MP34. When the internal clock ICK transitions from the high logic level to the low logic level, the precharge transistors MP31-MP34 are turned on, and the current source transistor MN20 is turned off. This operation supplies intermediate nodes N21 and N22 and output nodes NQP and NQN with a high level voltage (e.g., supply voltage Vdd), and the voltages of the output nodes NQP and NQN (i.e., the comparison signals QP and QN) are set to the high logic level. In addition, when the internal clock ICK transitions from the low logic level to the high logic level, the precharge transistors MP31-MP34 are turned off, and the current source transistor MN20 is turned on. Thus, a voltage level of the output node NQP or NQN transitions from the high logic level to the low logic level based on relationships of levels between the analog voltage Vs and the reference voltage VREF.

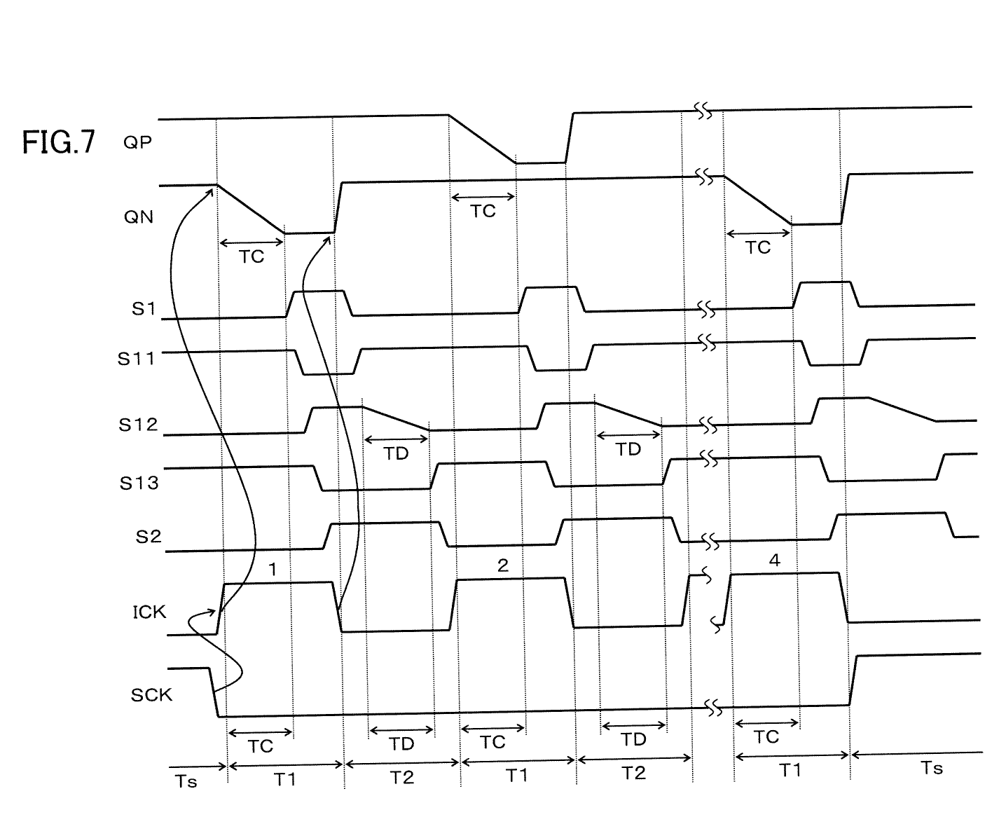

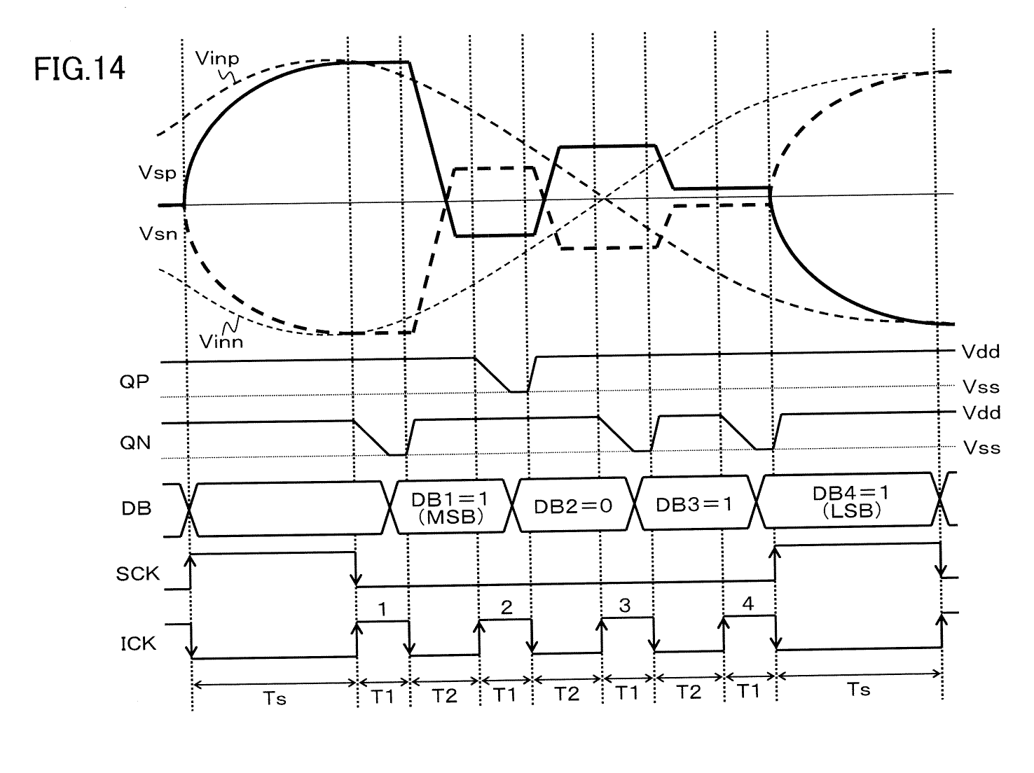

Note that, for purposes of facilitating the understanding of the operation of the differential latched comparator 22, the description provided above and FIG. 2 (and also the description provided below and FIGS. 7 and 14) assume that either the comparison signal QP or QN transitions from the high logic level to the low logic level in synchronism with a rising edge of the internal clock ICK. In fact, the operation of the differential latched comparator 22 can be described in detail as follows. First, when the internal clock ICK transitions from the low logic level to the high logic level, both of the voltages of the output nodes NQP and NQN start to transition from the high logic level to the low logic level. When the voltage of either the output node NQP or NQN reaches a threshold level of the latch transistor MN23, MN24, MP21, and MP22, the latch transistor MN23, MN24, MP21, and MP22 start to provide positive feedback. Thus, the higher one of the voltages of the output nodes NQP and NQN returns to the high logic level, and the lower one of the voltages of the output nodes NQP and NQN transitions to the low logic level. When the lower one of the voltages of the output nodes NQP and NQN reaches the low logic level, the voltages of the output nodes NQP and NQN stabilize. Moreover, the smaller the voltage difference between the analog voltage Vs and the reference voltage VREF is, the longer it takes for the positive feedback to be started. That is, the comparator delay time (time from when the internal clock ICK transitions from the low logic level to the high logic level until the comparison signals QP and QN stabilize) increases.

(Clock Generator Circuit)

Next, the clock generator circuit 10 shown in FIG. 1 will be described. The clock generator circuit 10 includes a sampling clock generator ii which generates the sampling clock SCK, an internal clock generator 12 which generates the internal clock ICK, and a delay controller 13.

[Sampling Clock Generator]

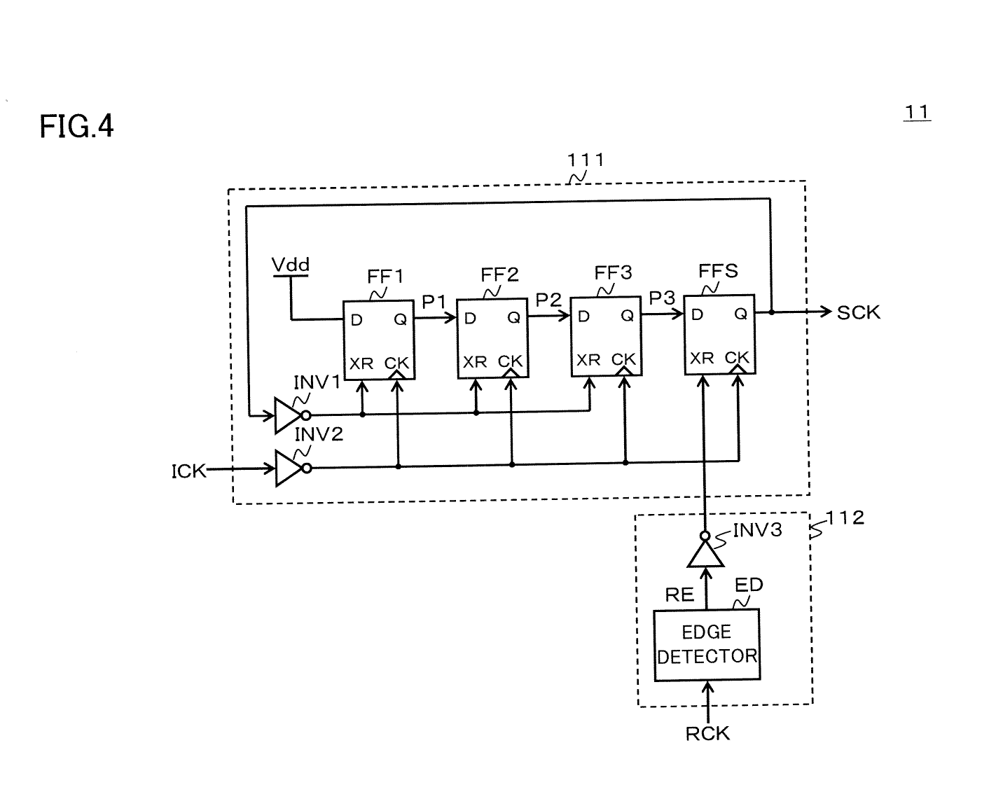

When the reference clock RCK (a clock which defines a sampling period of the successive approximation ADC 20) transitions from the low logic level to the high logic level, the sampling clock generator 11 causes a transition of the sampling clock SCK from the high logic level to the low logic level. In addition, during a low-level period of the sampling clock SCK, the sampling clock generator 11 causes a transition of the sampling clock SCK from the low logic level to the high logic level after transitions of the internal clock ICK from the high logic level to the low logic level have occurred n times (here n=4). For example, as shown in FIG. 4, the sampling clock generator 11 includes a counter 111 and a counter controller 112.

The counter 111 counts the number of transitions of the internal clock ICK from the high logic level to the low logic level during a low-level period of the sampling clock SCK, and causes a transition of the sampling clock SCK from the low logic level to the high logic level when the number of transitions reaches n (here n=4). For example, the counter 111 includes inverters INV1 and INV2 and n (here n=4) cascaded flip-flops FF1-FF3 and FFS. The inverter INV1 provides an inverted signal of the sampling clock SCK to the reset terminals of the flip-flops FF1-FF3. The inverter INV2 provides an inverted signal of the internal clock ICK to the clock terminals of the flip-flops FF1-FF3 and FFS. The flip-flops FF1-FF3 and FFS each capture the supply voltage Vdd (or the output of the immediately previous flip-flop) in synchronism with a rising edge of the inverted signal of the internal clock ICK (i.e., a falling edge of the internal clock ICK), and hold the captured signal. The flip-flop FFS provides the output signal thereof as the sampling clock SCK.

The counter controller 112 causes a transition of the sampling clock SCK from the high logic level to the low logic level when the reference clock RCK transitions from the low logic level to the high logic level. For example, the counter controller 112 includes an edge detector ED and an inverter INV3. The edge detector ED outputs a detection pulse RE when the edge detector ED detects a rising edge of the reference clock RCK. The inverter INV3 provides an inverted signal of the detection pulse RE to the reset terminal of the flip-flop FFS.

[Operation of Sampling Clock Generator]

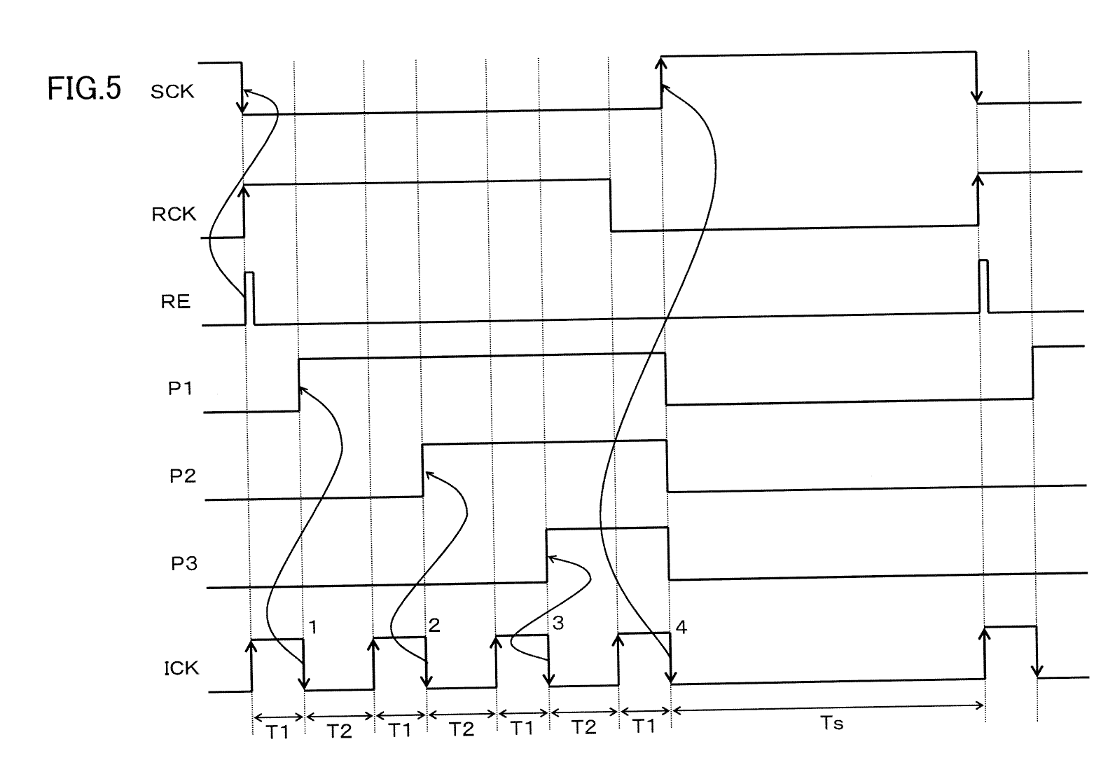

Next, referring to FIG. 5, the operation of the sampling clock generator 11 will be described.

When the reference clock RCK transitions from the low logic level to the high logic level, the edge detector ED outputs the detection pulse RE. This operation causes the flip-flop FFS to be reset, and the output signal of the flip-flop FFS (sampling clock SCK) to transition from the high logic level to the low logic level.

When the sampling clock SCK transitions from the high logic level to the low logic level, the reset states of the flip-flops FF1-FF3 are released. Thus, the flip-flops FF1, FF2, and FF3 respectively cause transitions of the output signals P1, P2, and P3 from the low logic level to the high logic level in synchronism with the first, second, and third falling edges of the internal clock ICK.

Next, the flip-flop FFS captures the output signal P3 of the flip-flop FF3 in synchronism with the fourth falling edge of the internal clock ICK. Thus, the state of output signals of the flip-flop FFS (sampling clock SCK) transitions from the low logic level to the high logic level. In addition, the flip-flops FF1-FF3 are reset, and the output signals P1-P3 transition from the high logic level to the low logic level.

[Internal Clock Generator]

During a high-level period of the sampling clock SCK, the internal clock generator 12 maintains the internal clock ICK at the low logic level. In addition, when the sampling clock SCK transitions from the high logic level to the low logic level, the internal clock generator 12 causes a transition of the internal clock ICK from the low logic level to the high logic level. Moreover, during a low-level period of the sampling clock SCK, the internal clock generator 12 causes a transition of the internal clock ICK from the high logic level to the low logic level when the comparison signals QP and QN transition from the same voltage level to the voltage levels different from each other, and causes a transition of the internal clock ICK from the low logic level to the high logic level after a variable delay time has elapsed when the comparison signals QP and QN transition from the voltage levels different from each other to the same voltage level. For example, as shown in FIG. 1, the internal clock generator 12 includes a NAND circuit 121 (first logic circuit), a variable delay unit 122, and a NOR circuit 123 (second logic circuit).

The NAND circuit 121 sets an internal signal S1 to a high logic level if the comparison signals QP and QN are at the voltage levels different from each other, and set the internal signal Si to a low logic level if the comparison signals QP and QN are at the same voltage level (here the high logic level).

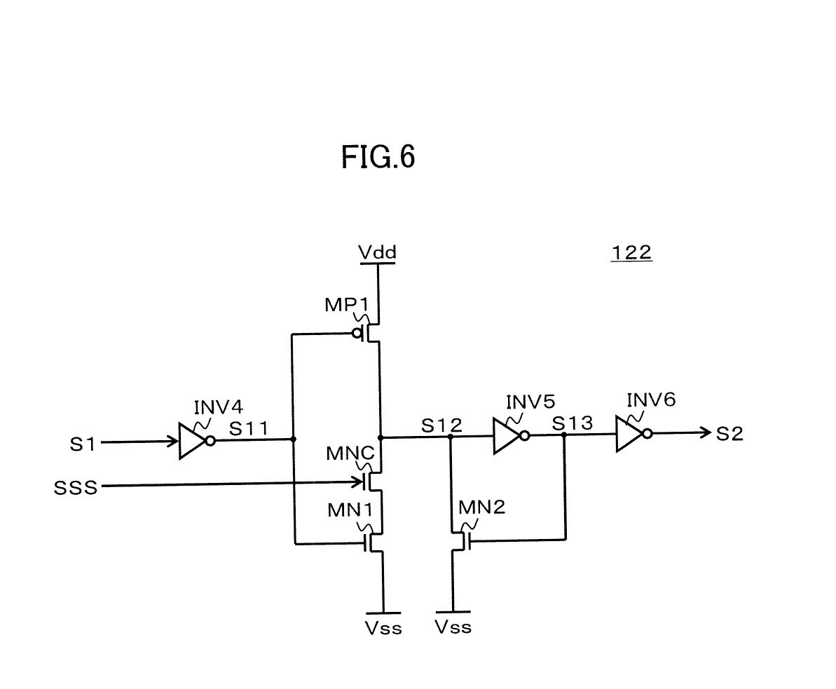

The variable delay unit 122 delays the transition of the internal signal S1 from the high logic level to the low logic level by the variable delay time, and outputs a resultant signal as a second internal signal S2. The variable delay time of the variable delay unit 122 is controlled by a delay control signal SSS. For example, as shown in FIG. 6, the variable delay unit 122 includes an inverter INV4, a pMOS transistor MP1 and nMOS transistors MNC and MN1 coupled in series, an inverter INV5, an nMOS transistor MN2, and an inverter INV6. With such a configuration, the lower the signal level of the delay control signal SSS is, the longer the delay time of a falling edge of the internal signal S12 is (i.e., the longer the variable delay time is).

The NOR circuit 123 sets the internal clock ICK to the high logic level if both of the sampling clock SCK and the internal signal S2 are at the low logic level, and sets the internal clock ICK to the low logic level if at least one of the sampling clock SCK and the internal signal S2 is at the high logic level.

[Operation of Internal Clock Generator]

Next, referring to FIG. 7, the operation of the internal clock generator 12 will be described.

During a high-level period of the sampling clock SCK, the output signal of the NOR circuit 123 (internal clock ICK) is maintained at the low logic level. In addition, the comparison signals QP and QN are maintained at the high logic level, and the output signal of the NAND circuit 121 (internal signal S1) and the output signal of the variable delay unit 122 (internal signal S2) are maintained at the low logic level.

When the sampling clock SCK transitions from the high logic level to the low logic level, both of the sampling clock SCK and the internal signal S2 transition to the low logic level, and the output signal of the NOR circuit 23 (internal clock ICK) transitions from the low logic level to the high logic level.

When the internal clock ICK transitions from the low logic level to the high logic level, the differential latched comparator 22 causes transitions of the comparison signals QP and QN from the same voltage level to the voltage levels different from each other based on which of the analog voltage Vs or the reference voltage VREF is higher. When the comparison signals QP and QN have transitioned to the voltage levels different from each other (a comparator delay time TC has elapsed), the output signal of the NAND circuit 121 (internal signal S1) transitions from the low logic level to the high logic level. This operation causes the internal signals S11, S12, and S13 to transition sequentially, the output signal of the variable delay unit 122 (internal signal S2) to transition from the low logic level to the high logic level, and the output signal of the NOR circuit 123 (internal clock ICK) to transition from the high logic level to the low logic level.

When the internal clock ICK transitions from the high logic level to the low logic level, the differential latched comparator 22 causes transitions of the comparison signals QP and QN from the voltage levels that are different from each other to the same voltage level. When the comparison signals QP and QN have transitioned to the same voltage level, the output signal of the NAND circuit 121 (internal signal S1) transitions from the high logic level to the low logic level. This operation causes the internal signals S11, S12, and S13 to transition sequentially, and the output signal of the variable delay unit 122 (internal signal S2) to transition from the high logic level to the low logic level. Note that the transition of the internal signal S2 from the high logic level to the low logic level is delayed by the variable delay time TD (a delay time of a falling edge of the internal signal S12). When the internal signal S2 transitions from the high logic level to the low logic level, the output signal of the NOR circuit 123 (internal clock ICK) transitions from the low logic level to the high logic level.

As described above, during a low-level period of the sampling clock SCK, when the delay time that includes the comparator delay time TC has elapsed after the internal clock ICK transitions from the low logic level to the high logic level, the internal clock ICK transitions from the high logic level to the low logic level. When the delay time that includes the variable delay time TD has elapsed after the internal clock ICK transitions from the high logic level to the low logic level, the internal clock ICK transitions from the low logic level to the high logic level. That is, a high-level period T1 of the internal clock ICK includes the comparator delay time TC, and a low-level period T2 of the internal clock ICK includes the variable delay time TD.

Next, during a low-level period of the sampling clock SCK, when the n-th (here n=4) falling edge of the internal clock ICK occurs, the sampling clock generator 11 causes a transition of the sampling clock SCK from the low logic level to the high logic level. Thus, the output signal of the NOR circuit 123 (internal clock ICK) is maintained at the low logic level.

[Delay Controller]

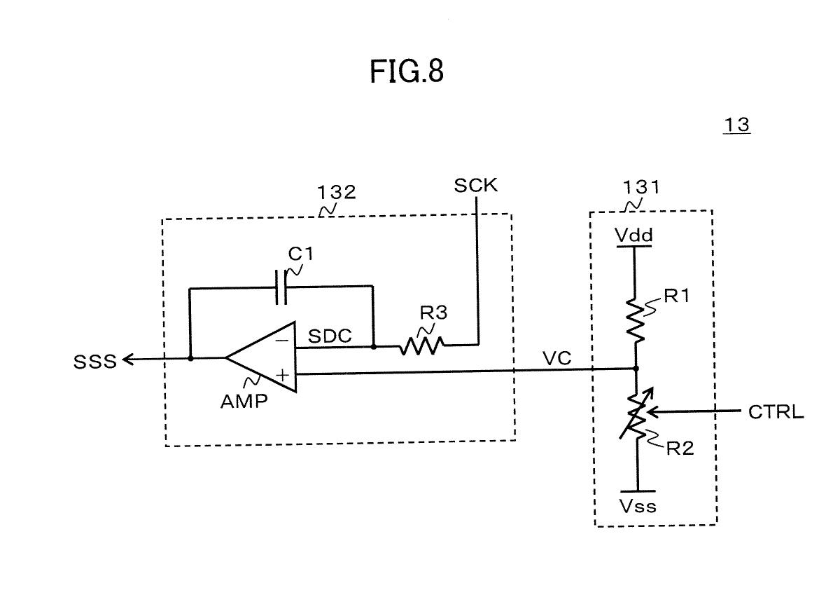

The delay controller 13 controls the variable delay time in the internal clock generator 12 so that the ratio of the high-level period Ts of the sampling clock SCK to the period Tck of the reference clock RCK (represented hereinafter as the period ratio Ts/Tck) approaches a predetermined ratio (X %). For example, as shown in FIG. 8, the delay controller 13 includes a voltage generator 131 and a ratio controller 132.

The voltage generator 131 controls the control voltage VC so that the ratio of the voltage level of the control voltage VC to the high logic level (here, the supply voltage Vdd) of the sampling clock SCK (represented hereinafter as the voltage ratio VCNdd) is the predetermined ratio (X %). For example, the voltage generator 131 includes resistive elements R1 and R2 coupled in series between the power supply node (a node to which the supply voltage Vdd is applied) and the ground node (a node to which the ground voltage Vss is applied). The control voltage VC is generated by resistance division with the resistive elements R1 and R2. It is assumed here that the resistance value of the resistive element R2 can be changed by a control signal CTRL. That is, the voltage ratio VC/Vdd (predetermined ratio (X %)) can be changed by the control signal CTRL.

The ratio controller 132 increases or decreases the signal level of the delay control signal SSS (a signal for controlling the variable delay time in the internal clock generator 12) so that the DC level (here, an intermediate voltage SDC) of the sampling clock SCK approaches the voltage level of the control voltage VC. For example, the ratio controller 132 includes a resistive element R3, a capacitive element C1, and a differential amplifier AMP. In the configuration shown in FIG. 8, an inverting input terminal (−) and a non-inverting input terminal (+) of the differential amplifier AMP are respectively supplied with the intermediate voltage SDC (the voltage corresponding to progressive average power of the sampling clock SCK) and the control voltage VC. Since a virtual short circuit is produced between the non-inverting and inverting input terminals of the differential amplifier AMP, the signal level of the delay control signal SSS is controlled so that the amount of charge charged in the capacitor C1 (amount of charged charge) during a high-level period of the sampling clock SCK and the amount of charge discharged from the capacitor C1 (amount of discharged charge) during a low-level period of the sampling clock SCK are equal to each other.

Here, let Q1 denote the amount of charged charge and let Q2 denote the amount of discharged charge. Then, the following equations hold:

Q1=Ts·(Vdd−VC)/R3 [Eq. 1]

Q2=(Tck−Ts)·VC/R3 [Eq. 2]

Since the signal level of the delay control signal SSS is controlled so that Q1=Q2, the following equation is obtained:

Ts·(Vdd−VC)/R3=(Tck−Ts)·VC/R3 [Eq. 3]

Eq. 3 can be rewritten as the following equation.

Ts/Tck=VC/Vdd [Eq. 4]

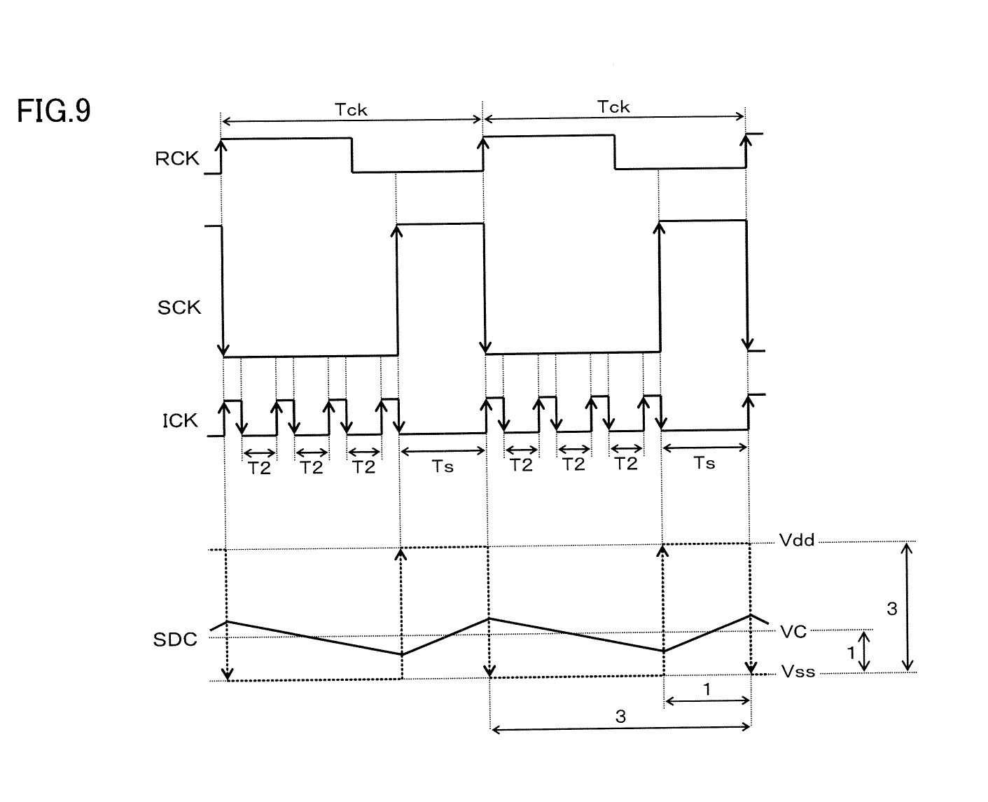

Eq. 4 shows that the period ratio Ts/Tck is equivalent to the voltage ratio VC/Vdd. Thus, increasing or decreasing the signal level of the delay control signal SSS so that the DC level of the intermediate voltage SDC (i.e., the DC level of the sampling clock SCK) approaches the voltage level of the control voltage VC allows, as shown in FIG. 9, the period ratio Ts/Tck to approach the voltage ratio VC/Vdd (predetermined ratio (X %)). For example, if the period ratio Ts/Tck is higher than the voltage ratio VC/Vdd, then the DC level of the intermediate voltage SDC is higher than the voltage level of the control voltage VC. In such a case, the ratio controller 132 decreases the signal level of the delay control signal SSS. This operation causes the variable delay time TD in the internal clock generator 12 to be increased, thereby increasing the low-level period T2 of the internal clock ICK. As a result, the high-level period Ts of the sampling clock SCK is decreased, thereby decreasing the period ratio Ts/Tck.

Note that, if the differential amplifier AMP has an ideal amplification characteristic (e.g., if the differential amplifier AMP has an infinite gain), the voltage level of the intermediate voltage SDC stabilizes at the voltage level of the control voltage VC. That is, the intermediate voltage SDC becomes exactly the same as the control voltage VC. In contrast, if the differential amplifier AMP does not have an ideal amplification characteristic (e.g., if the differential amplifier AMP has a finite gain), the waveform of the intermediate voltage SDC is, as shown in FIG. 9, a triangle wave having a DC level equivalent to the voltage level of the control voltage VC.

As described above, each of the n high-level periods of the internal clock ICK includes the comparator delay time TC, thereby allowing the comparison time (the time needed for the differential latched comparator 22 to perform the comparison process) to be ensured in each of the n high-level periods T1 of the internal clock ICK.

In addition, controlling the variable delay time TD so that the period ratio Ts/Tck approaches the predetermined ratio (X %) allows the high-level period Ts of the sampling clock SCK to be ensured, and the n high-level periods T1 of the internal clock ICK to be accommodated within the low-level period of the sampling clock SCK.

Moreover, the remaining period (Tck−Ts−n·T1) which is obtained by subtracting the n high-level periods Ti of the internal clock ICK from the low-level period of the sampling clock SCK can be distributed nearly evenly as (n−1) low-level periods T2 of the internal clock ICK. This characteristic facilitates ensuring the charge redistribution time (the time needed for the capacitive DAC 21 to perform the charge redistribution process) in each of the (n−1) low-level periods T2 of the internal clock ICK.

(Ratio Control)

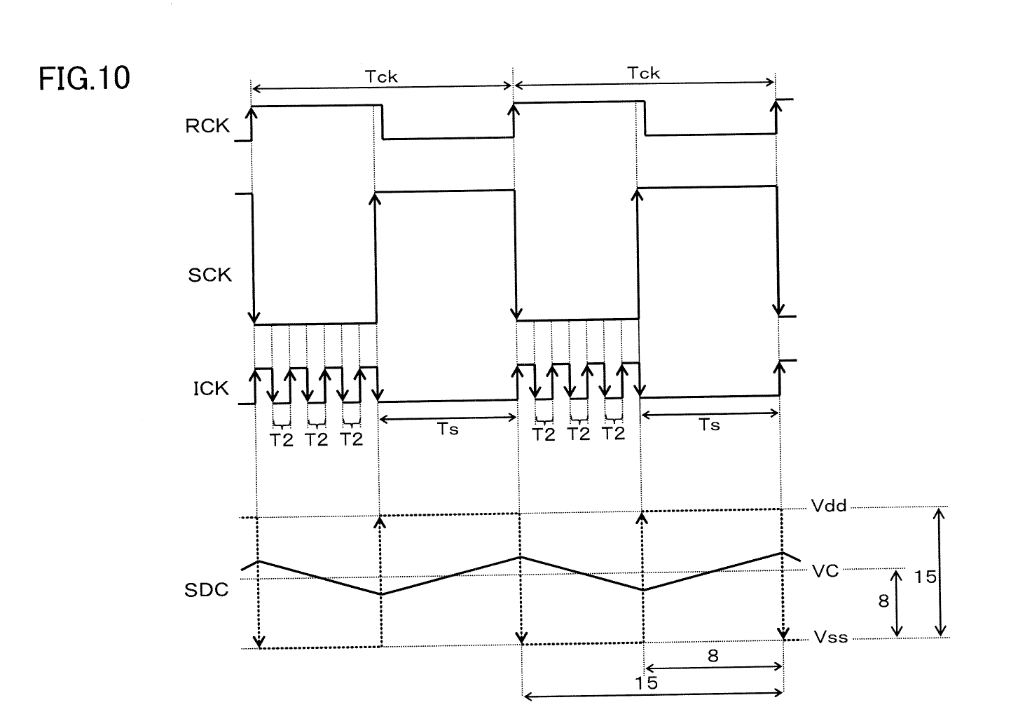

As shown in FIG. 10, changing the voltage ratio VC/Vdd (i.e., the predetermined ratio (X %)) by the control signal CTRL allows the period ratio Ts/Tck to be changed. That is, the high-level period Ts of the sampling clock SCK can be adjusted. Thus, the high-level period Ts of the sampling clock SCK can be appropriately set based on the specifications (e.g., a settling time in a sampling process) of the successive approximation ADC 20. Note that the predetermined ratio (X %) may be a fixed value. For example, the resistor R2 may be a fixed resistor.

(Variation of Sampling Clock Generator)

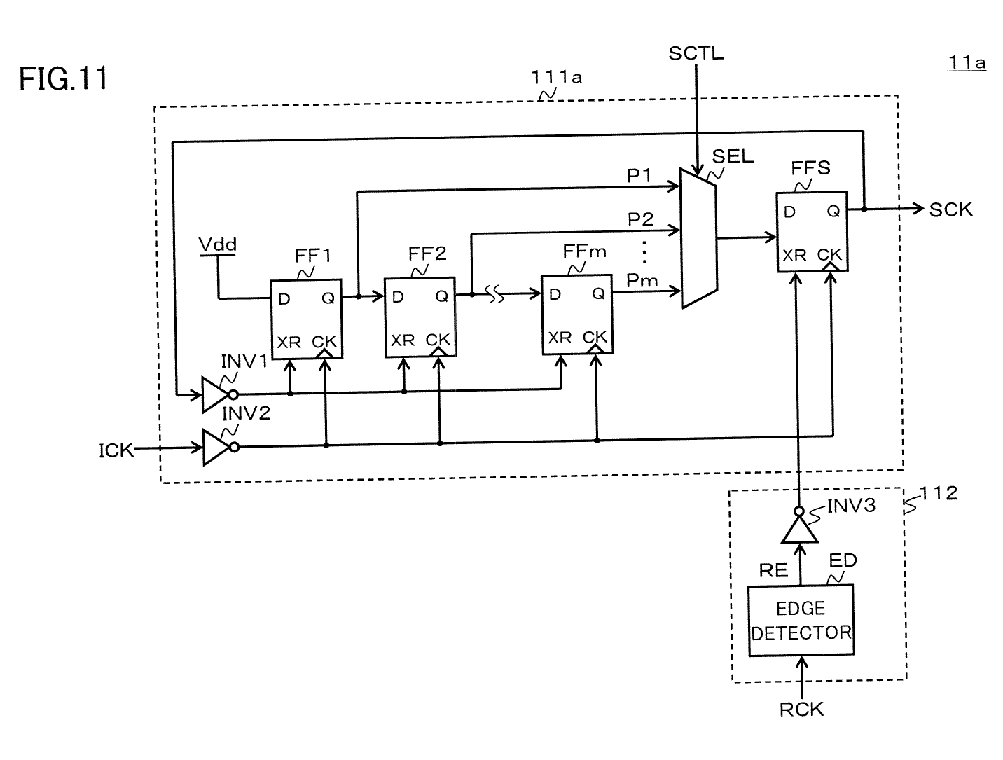

The clock generator circuit 10 may include a sampling clock generator 11a shown in FIG. 11 in place of the sampling clock generator 11 shown in FIG. 1. The sampling clock generator 1 la includes a variable counter 111a in place of the counter 111 shown in FIG. 1. The variable counter 111a includes inverters INV1 and INV2, m cascaded flip-flops FF1-FFm, a selector SEL, and a flip-flop FFS. The inverter INV1 provides an inverted signal of the sampling clock SCK to the reset terminals of the flip-flops FF1-FFm. The inverter INV2 provides an inverted signal of the internal clock ICK to the clock terminals of the flip-flops FF1-FFm and FFS. The flip-flops FF1-FFm each capture the supply voltage Vdd (or the output signal of the immediately previous flip-flop) in synchronism with a rising edge of the inverted signal of the internal clock ICK (i.e., a falling edge of the internal clock ICK), and hold the captured signal. The selector SEL selects one of the output signals P1-Pm of the flip-flops FF1-FFm in response to a selection control signal SCTL. The flip-flop FFS captures the output signal selected by the selector SEL from the output signals P1-Pm, and holds the captured signal.

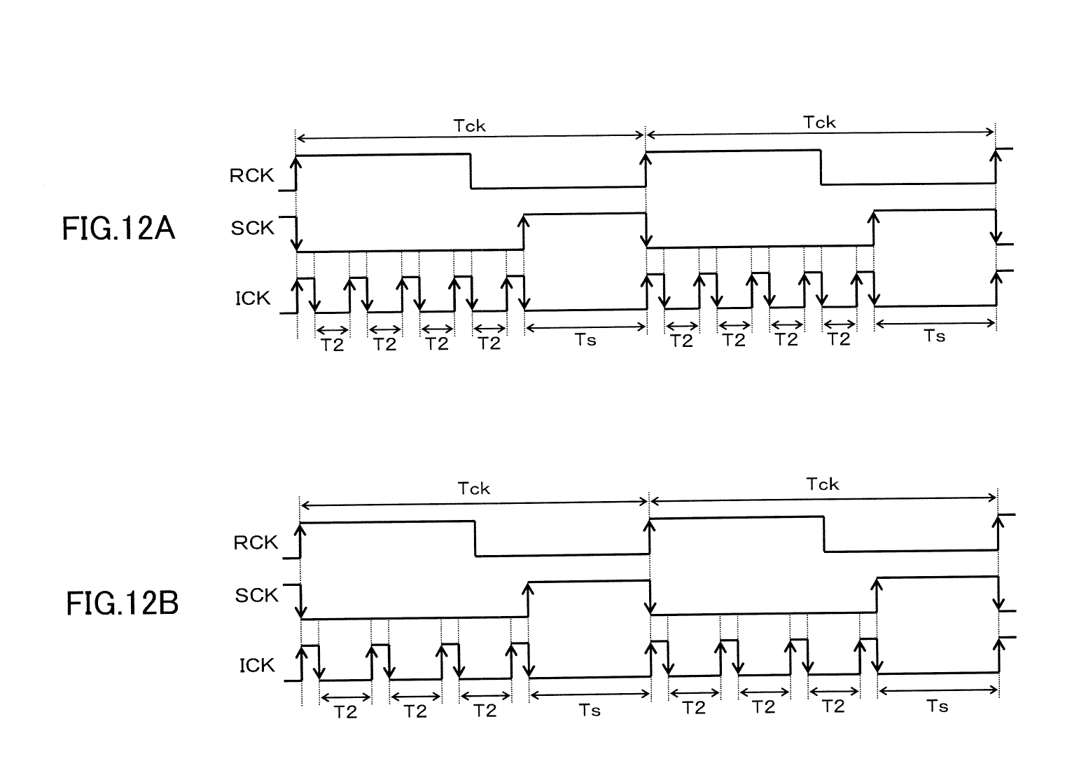

For example, if the fourth output signal P4 is selected by the selector SEL, then as shown in FIG. 12A, the number of pulses of the internal clock ICK (number of the high-level periods T1) is “5”; if the third output signal P3 is selected by the selector SEL, then as shown in FIG. 12B, the number of pulses of the internal clock ICK is “4.”

As described above, the number of pulses of the internal clock ICK can be adjusted by the selection control signal SCTL. This configuration allows the number of pulses of the internal clock ICK to be set based on the specifications of the successive approximation ADC 20 (e.g., the number of bits of the successive approximation ADC 20).

(Variation of Successive Approximation ADC)

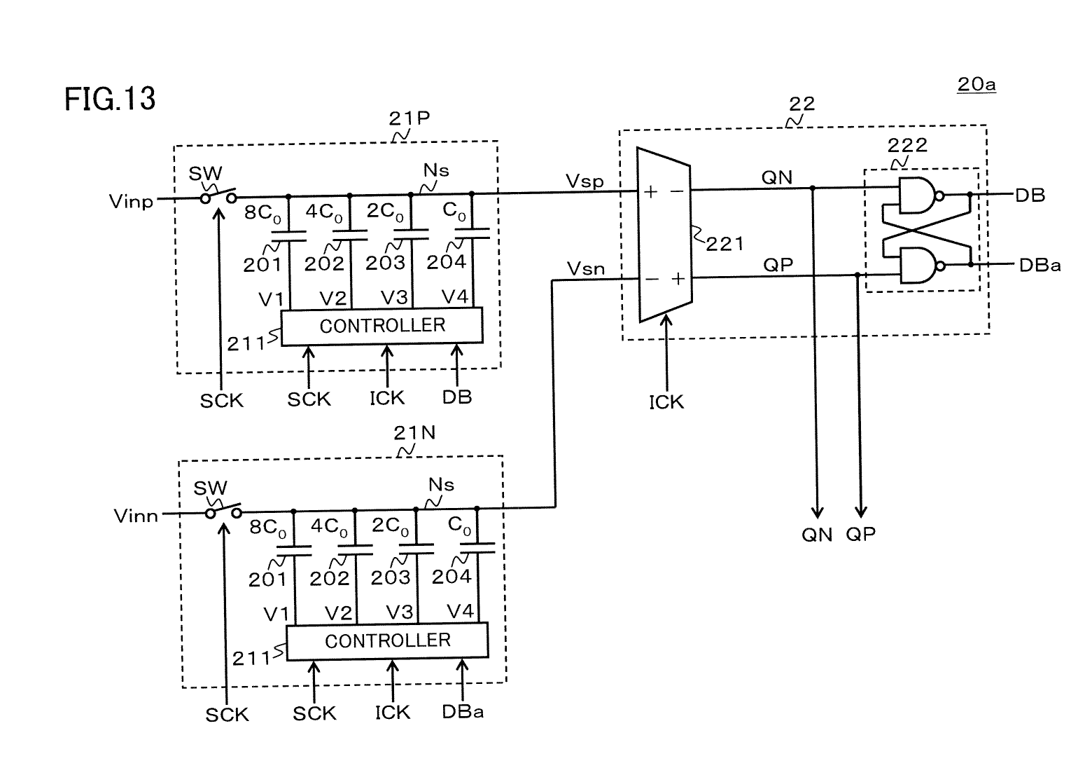

The clock generator circuit 10 can also be applied to a differential successive approximation ADC 20a shown in FIG. 13. The successive approximation ADC 20a shown in FIG. 13 converts a differential voltage between analog signals Vinp and Vinn, whose voltage levels vary in a complementary fashion with respect to each other, into an n-bit (here n=4) digital signal. The successive approximation ADC 20a includes capacitive DACs 21P and 21N, and a differential latched comparator 22. The capacitive DACs 21P and 21N each have a configuration similar to that of the capacitive DAC 21 shown in FIG. 1. The controller 211 of the capacitive DAC 21P controls the control voltages V1-V4 based on the bit value DB, and the controller 211 of the capacitive DAC 21N controls the control voltages V1-V4 based on the bit value DBa (inverted value of the bit value DB).

During a high-level period Ts of the sampling clock SCK, the capacitive DACs 21P and 21N respectively store electrical charges dependent on the signal levels of the analog signals Vinp and Vinn, and respectively sample analog voltages Vsp and Vsn dependent on the analog signals Vinp and Vinn. During a high-level period T1 of the internal clock ICK, the differential latched comparator 22 causes transitions of the comparison signals QP and QN to voltage levels different from each other based on which of the analog voltage Vsp or Vsn is higher, and outputs a bit value DB dependent on the comparison signals QP and QN as the digital signal. During a low-level period T2 of the internal clock ICK, the differential latched comparator 22 causes transitions of the comparison signals QP and QN to a same voltage, and holds the bit value DB. The capacitive DACs 21P and 21N respectively control the electrical charges stored in the capacitive DACs 21P and 21N based on the bit values DB and DBa so that the analog voltages Vsp and Vsn approach each other (see FIG. 14).

Note that the clock generator circuit 10 may also be applied to successive approximation ADCs having configurations other than those shown in FIGS. 1 and 13.

As described above, the clock generator circuit described above is useful as a clock generator circuit for a successive approximation ADC.

It is to be understood that the foregoing embodiments are illustrative in nature, and are not intended to limit the scope of the invention, application of the invention, or use of the invention.

What is claimed is:

1. A clock generator circuit for generating a sampling clock and an internal clock used in a successive approximation analog-to-digital converter (ADC) which converts a first analog signal and a second analog signal, whose voltage levels vary in a complementary fashion with respect to each other, into an n-bit (where n≧2) digital signal, where the successive approximation ADC includes a first capacitive digital-to-analog converter (DAC), a second capacitive DAC, and a differential latched comparator, comprising:
a sampling clock generator configured to generate the sampling clock;
an internal clock generator configured to generate the internal clock; and
a delay controller,
wherein
during a period in which the sampling clock is at a first voltage level, the first and second capacitive DACs respectively store electrical charges dependent on signal levels of the first and second analog signals, and respectively sample a first analog voltage and a second analog voltage dependent on the signal levels of the first and second analog signals,
during a period in which the internal clock is at a first voltage level, the differential latched comparator changes voltages of a first comparison signal and a second comparison signal to voltage levels different from each other based on which of the first or second analog voltage is higher, and outputs as the digital signal a bit value dependent on the first and second comparison signals,
during a period in which the internal clock is at a second voltage level, the differential latched comparator changes the voltages of the first and second comparison signals to a same voltage level, and holds the bit value, and the first and second capacitive DACs respectively control the electrical charges stored in the first and second capacitive DACs based on the bit value so that the first and second analog voltages approach each other,
the sampling clock generator causes the sampling clock to transition from the first voltage level to a second voltage level when a reference clock, which defines a sampling period of the successive approximation ADC, transitions from a second voltage level to a first voltage level, and causes the sampling clock to transition from the second voltage level to the first voltage level after transitions of the internal clock from the first voltage level to the second voltage level have occurred n times during a period in which the sampling clock is at the second voltage level,
the internal clock generator maintains the internal clock at the second voltage level during the period in which the sampling clock is at the first voltage level, causes the internal clock to transition from the second voltage level to the first voltage level when the sampling clock transitions from the first voltage level to the second voltage level, and causes, during the period in which the sampling clock is at the second voltage level, the internal clock to transition from the first voltage level to the second voltage level when the first and second comparison signals transition from the same voltage level to the voltage levels different from each other, and the internal clock to transition from the second voltage level to the first voltage level after a variable delay time has elapsed when the first and second comparison signals transition from the voltage levels different from each other to the same voltage level, and
the delay controller controls the variable delay time in the internal clock generator so that a ratio of the period in which the sampling clock is at the first voltage level to a period of the reference clock approaches a predetermined ratio.

2. A clock generator circuit for generating a sampling clock and an internal clock used in a successive approximation analog-to-digital converter (ADC) which converts an analog signal into an n-bit (where n≧2) digital signal, where the successive approximation ADC includes a capacitive digital-to-analog converter (DAC) and a differential latched comparator, comprising:
a sampling clock generator configured to generate the sampling clock;
an internal clock generator configured to generate the internal clock; and
a delay controller,
wherein
during a period in which the sampling clock is at a first voltage level, the capacitive DAC stores an electrical charge dependent on a signal level of the analog signal, and samples an analog voltage dependent on the signal level of the analog signal,
during a period in which the internal clock is at a first voltage level, the differential latched comparator changes voltages of a first comparison signal and a second comparison signal to voltage levels different from each other based on which of a reference voltage or the analog voltage is higher, and outputs as the digital signal a bit value dependent on the first and second comparison signals,
during a period in which the internal clock is at a second voltage level, the differential latched comparator changes the voltages of the first and second comparison signals to a same voltage level, and holds the bit value, and the capacitive DAC controls the electrical charge stored in the capacitive DAC based on the bit value so that the analog voltage approaches the reference voltage,
the sampling clock generator causes the sampling clock to transition from the first voltage level to a second voltage level when a reference clock, which defines a sampling period of the successive approximation ADC, transitions from a second voltage level to a first voltage level, and causes the sampling clock to transition from the second voltage level to the first voltage level after transitions of the internal clock from the first voltage level to the second voltage level have occurred n times during a period in which the sampling clock is at the second voltage level,
the internal clock generator maintains the internal clock at the second voltage level during the period in which the sampling clock is at the first voltage level, causes the internal clock to transition from the second voltage level to the first voltage level when the sampling clock transitions from the first voltage level to the second voltage level, and causes, during the period in which the sampling clock is at the second voltage level, the internal clock to transition from the first voltage level to the second voltage level when the first and second comparison signals transition from the same voltage level to the voltage levels different from each other, and the internal clock to transition from the second voltage level to the first voltage level after a variable delay time has elapsed when the first and second comparison signals transition from the voltage levels different from each other to the same voltage level, and
the delay controller controls the variable delay time in the internal clock generator so that a ratio of the period in which the sampling clock is at the first voltage level to a period of the reference clock approaches a predetermined ratio.

3. The clock generator circuit of claim 1, wherein
the internal clock generator includes
a first logic circuit configured to set a first internal signal to a first voltage level if the first and second comparison signals are at the voltage levels different from each other, and to set the first internal signal to a second voltage level if the first and second comparison signals are at the same voltage level,
a variable delay unit configured to delay the transition of the first internal signal from the first voltage level to the second voltage level by the variable delay time, and
to output a resultant signal as a second internal signal, and a second logic circuit configured to set the internal clock to the first voltage level if both of the sampling clock and the second internal signal are at the second voltage level, and to set the internal clock to the second voltage level if at least one of the sampling clock and the second internal signal is at the first voltage level.

4. The clock generator circuit of claim 1, wherein
the delay controller includes
a voltage generator configured to generate a control voltage so that a ratio of a voltage level of the control voltage to the first voltage level of the sampling clock is the predetermined ratio, and
a ratio controller configured to control the variable delay time in the internal clock generator so that a DC level of the sampling clock approaches the voltage level of the control voltage.

5. The clock generator circuit of claim 1, wherein
the sampling clock generator includes
a counter configured, during the period in which the sampling clock is at the second voltage level, to count a number of transitions of the internal clock from the first voltage level to the second voltage level, and cause the sampling clock to transition from the second voltage level to the first voltage level when the number of transitions reaches the value n, and
a counter controller configured to cause the sampling clock to transition from the first voltage level to the second voltage level when the reference clock transitions from the second voltage level to the first voltage level.

6. The clock generator circuit of claim 1, wherein
the predetermined ratio can be variably controlled.

7. The clock generator circuit of claim 1, wherein
the value n can be variably controlled.

8. The clock generator circuit of claim 2, wherein
the internal clock generator includes
a first logic circuit configured to set a first internal signal to a first voltage level if the first and second comparison signals are at the voltage levels different from each other, and to set the first internal signal to a second voltage level if the first and second comparison signals are at the same voltage level,
a variable delay unit configured to delay the transition of the first internal signal from the first voltage level to the second voltage level by the variable delay time, and to output a resultant signal as a second internal signal, and
a second logic circuit configured to set the internal clock to the first voltage level if both of the sampling clock and the second internal signal are at the second voltage level, and to set the internal clock to the second voltage level if at least one of the sampling clock and the second internal signal is at the first voltage level.

9. The clock generator circuit of claim 2, wherein
the delay controller includes
a voltage generator configured to generate a control voltage so that a ratio of a voltage level of the control voltage to the first voltage level of the sampling clock is the predetermined ratio, and
a ratio controller configured to control the variable delay time in the internal clock generator so that a DC level of the sampling clock approaches the voltage level of the control voltage.

10. The clock generator circuit of claim 2, wherein
the sampling clock generator includes
a counter configured, during the period in which the sampling clock is at the second voltage level, to count a number of transitions of the internal clock from the first voltage level to the second voltage level, and cause the sampling clock to transition from the second voltage level to the first voltage level when the number of transitions reaches the value n, and
a counter controller configured to cause the sampling clock to transition from the first voltage level to the second voltage level when the reference clock transitions from the second voltage level to the first voltage level.

11. The clock generator circuit of claim 2, wherein
the predetermined ratio can be variably controlled.

12. The clock generator circuit of claim 2, wherein
the value n can be variably controlled.
